(19) United States
(12) Patent Application Publication
(10) Pub. No.: US 2002/0053717 A1
(43) Pub. Date: May 9, 2002

(54) SEMICONDUCTOR APPARATUS

(76) Inventor: HITOSHI SUMIDA, NAGANO (JP)

Correspondence Address: MARC A ROSSI, ROSSI & ASSOCIATES, PO BOX 826, ASHBURN, VA, 201460826

(21) Appl. No.: 09/004,559

(22) Filed: Jan. 8, 1998

(30) Foreign Application Priority Data
Jan. 9, 1997 (JP) PA 09-001781

(51) Int. Cl. H01L 27/082

(52) U.S. Cl. 257/565

(57) ABSTRACT

In a semiconductor apparatus having a dielectric isolation substrate formed by laminating a first oxide film on a first or second conductivity type first semiconductor substrate and laminating a first conductivity type second semiconductor substrate on the first oxide film, a trench is formed through the second semiconductor substrate down to the first oxide film, and a surface of the second semiconductor substrate that defines the trench is covered with a second oxide film. The trench is filled with a polycrystalline semiconductor material so as to provide a dielectric isolation region, and the second semiconductor substrate is divided by the trench into a plurality of isolated regions. In this semiconductor apparatus, at least a lateral insulated gate bipolar transistor and a lateral diode are formed in the same one of the isolated regions. In another embodiment, at least a lateral insulated gate bipolar transistor and a lateral MOSFET are formed in the same isolated region.

### FIELD OF THE INVENTION

The present invention relates to a semiconductor apparatus, such as a high voltage power IC, wherein high voltage lateral insulated gate bipolar transistors and other lateral semiconductor devices, along with circuits for driving, control and protecting these devices, are integrated on a dielectric isolation substrate formed by combining laminated substrates with trench isolation regions (trenches) that divide the substrate into a plurality of isolated regions.

### BACKGROUND OF THE INVENTION

With recent progress in isolation techniques, such as junction isolation and dielectric isolation, high voltage power integrated circuits (IC) have been extensively developed in which high voltage lateral devices, such as diodes, insulated gate bipolar transistors (hereinafter abbreviated to “IGBT”), and MOSFET, along with circuits for driving, controlling and protecting these devices, are integrated on a single silicon substrate. In particular, the development of dielectric isolation technique of SOI type that utilizes a combination of laminated substrates and trench isolation regions makes it possible to produce power IC on which a plurality of high voltage devices are integrated, assuring a further increased withstand voltage. For example, there have been developed totem-pole circuits in which high voltage devices, such as IGBT, are integrated on one chip, and IC for driving a display which uses high voltage devices, such as IGBT, to produce a multiplicity of outputs. It is to be understood that “SOI” mentioned above is an abbreviation of “Semiconductor On Insulator”.

FIG. 12 is a cross sectional view showing a principal part of a typical example of known semiconductor apparatus wherein lateral IGBT and lateral diode are formed in a dielectric isolation substrate. The lateral IGBT used in this example is of n channel type. A first oxide film 2 is laminated on an n type or p type first semiconductor substrate 1, and an n type second semiconductor substrate 3 is laminated on the first oxide film 2 over the first semiconductor substrate 1, to thus form a SOI substrate. The second semiconductor substrate 3 is divided into a plurality of isolated regions by a trench (trench isolation region) that is formed through the substrate 3 down to the first oxide film 2. A surface of the second semiconductor substrate 3 that defines the trench is covered with a second oxide film 14, and the trench is filled with polycrystalline silicon 15, so as to form the trench isolation region 155. Thus, a dielectric isolation substrate 123 consisting of the first and second semiconductor substrates 1, 2 and trench isolation region 155 is formed. The lateral IGBT and lateral diode are separately formed in respective isolated regions that are formed in the dielectric isolation substrate 123 and isolated from each other by the trench isolation region 155.

A method for forming a single lateral IGBT will be now described. A p well region 4 is formed in a surface layer of one of the isolated regions of the n-type semiconductor substrate 3, and an n buffer region 7 is formed apart from the p well region 4. An n⁺ emitter region 6 is formed in a surface layer of the p well region 4, and a p⁺ contact region 5 is formed in the p well region 4 so as to improve contact of the emitter region 6 with an emitter electrode 51. A gate electrode 52 made of polycrystalline silicon is formed on a gate insulating film 13 over a portion of the p well region 4 that is interposed between the n type semiconductor substrate 3 and the n⁺ emitter region 6. The emitter electrode 51 is formed on the n⁺ emitter region 6 and p⁺ contact region 5. On the other hand, a p⁺ collector region 8 is formed in a surface layer of the n buffer region 7, and a collector electrode 53 is formed on the p⁺ collector region 8. The emitter electrode 51 is connected to an emitter terminal E, and the collector electrode 53 is connected to a collector terminal C.

A method of forming the lateral diode will be next described. A p diffusion region 11 and an n diffusion region 9 are formed in a surface layer of another isolated region of the n type semiconductor substrate 3, such that these diffusion regions 11, 9 are spaced apart from each other. A p⁺ anode region 12 is formed in a surface layer of the p diffusion region 11, and an n⁺ cathode region 10 is formed in a surface layer of the n diffusion region 9. Anode electrode 54 and cathode electrode 55 are formed on the p⁺ anode region 12 and n⁺ cathode region 10, respectively, and the anode electrode 54 is connected to an anode terminal A while the cathode electrode 55 is connected to a cathode terminal K. Further, the emitter terminal E of the lateral IGBT is connected to the anode terminal A of the lateral diode, and the collector terminal C of the lateral IGBT is connected to the cathode electrode K of the lateral diode.

FIG. 13 contains a plan view and a cross sectional view of a part of the known example of FIG. 12 in which the lateral IGBT and lateral diode are formed side by side with a spacing therebetween. The plan view shows a pattern of the emitter and others of the lateral IGBT, cathode and others of the lateral diode, and trench isolation region, through electrodes are omitted in this figure.

Next, the operation of the lateral IGBT will be described referring to the cross sectional view of FIG. 12. When a voltage is applied so that the potential of the gate electrode 52 becomes higher than that of the emitter electrode 51, an n channel is formed in a portion of the p well region 4 located right under the gate electrode 52. At the same time, a voltage is applied so that the potential of the collector electrode 53 becomes higher than that of the emitter electrode 51, and therefore electrons as majority carriers are injected from the n⁺ emitter region 6 into the second semiconductor substrate 3 through the above n channel, thus producing an electron current iₑ. As a result, a pn junction between the p⁺ collector region 8 and the n buffer region 7 is strongly forward-biased due to these injected electrons, and holes as minority carriers are injected from the p⁺ collector region 8 into the second semiconductor substrate 3 through the n buffer region 7, thus producing a hole current iₕ. Thus, excess carriers provided by the thus injected electrodes and holes are stored in the second semiconductor substrate 3, whereby the conductivity of the second semiconductor substrate 3 is modulated so that the IGBT is turned on with a low ON-state voltage.

When the IGBT is turned off, the voltage applied to the gate electrode 52 is controlled to be lower than a threshold level, so that the n channel disappears, and injection of electrons from the n⁺ emitter region 6 is stopped.

As described above, the IGBT of the above example can achieve a sufficiently low ON-state voltage owing to the conductivity modulation. Also, the lateral IGBT formed on the SOI substrate can be turned off at a far higher speed as compared with the case when IGBT is formed on a junction isolation substrate, since electrons and holes are recombined at a high speed at the interface between the second semiconductor substrate 3 and the first oxide film 2, and a relatively small number of carriers are stored at the time of turn-on. In view of these advantages, the high voltage IGBT formed on the dielectric isolation substrate is preferably employed as an output-stage device of the power IC. Also, the dielectric isolation substrate has narrower isolation regions for isolating the devices from each other, as compared with the junction separation substrate, thus making it possible to produce high-voltage, large-current power IC having a relatively small chip area.

In a normal operating mode of the lateral IGBT as described above, the potential of the collector electrode 53 is kept higher than or positive relative to that of the emitter electrode 51. Depending upon applications, however, the IGBT is placed in a different operating mode, called reverse conduction state, in which the emitter potential becomes momentarily higher than the collector potential . Where an L load, such as a motor, is connected to an inverter circuit as shown in FIG. 10 (the load that is not illustrated is connected to outputs U, V, W of the inverter circuit), a regenerative mode due to inductance of the motor is established, and the circuit is brought into the reverse conduction state. A circuit that involves a capacity load, such as that for driving a plasma display panel, also has an operating mode that leads to the reverse conduction state.

The lateral IGBT may be configured so as to provide a MOSFET structure having a parasitic diode in which a part of the p⁺ collector region is short-circuited by an n⁺ short region, so that the current flowing in the above-described reverse conduction state is caused to flow through the n⁺ short region. If the rate of flow of short-circuit current is increased in this method so as to increase the conducting capability in the reverse conduction state, however, the ON-state voltage that is a forward-direction characteristic of the lateral IGBT is undesirably increased. For this reason, the rate of flow of the short-circuit current cannot be increased so much. Thus, there is a limit to the above-described method in which the current set up in the reverse conduction state is caused to flow the parasitic diode formed by the n⁺ short region.

FIG. 11(a) shows a circuit configuration in which the current flows upon reverse conduction through parasitic diodes of MOSFET, and FIG. 11(b) shows a circuit configuration in which individual diodes are connected in parallel with respective IGBT, so that the current flows through these diodes in the reverse conduction state. In FIG. 11(b ), the parasitic diodes 20 of the MOSFET 19 are indicated by dotted lines. In FIG. 11(b ), the diodes 23 through which the current flows in the reverse conduction state are connected in parallel with the respective IGBT 22. Generally, the circuit configuration of FIG. 11(b ) is preferably employed for the above-described reason.

A high voltage lateral diode may be formed in parallel with a high voltage lateral IGBT on a dielectric isolation substrate, as shown in FIG. 12. In this case, the high voltage lateral IGBT and high voltage lateral diode are isolated or separated from each other by the trench isolation region 155, such that these devices are separately formed in respective isolated regions.

When the high voltage devices as described above are formed on the dielectric isolation substrate, these devices need be spaced a sufficiently large distance from the trench isolation region 155. Namely, defects produced during formation of a trench are present in the vicinity of the trench that provides the trench isolation region 155, and therefore buffer regions need to be provided for eliminating influences of these defects on characteristics of the devices.

FIG. 14 is a cross sectional view of a principal part of the known example in the vicinity of the trench isolation region. Each of the high voltage devices needs to be formed with a spacing of 30 μm or larger from the trench isolation region 155. Thus, a buffer region 81 having a width of 30 μm or larger is provided between the trench isolation region 155 and each of the high voltage devices, i.e., the lateral IGBT and the lateral diode. The lateral diode needs to be provided for allowing flow of reverse current when the lateral IGBT is reverse-biased, and the provision of such diode requires areas of the buffer regions 81 around the trench isolation region 155, in addition to an area in which the lateral diode is formed.

As described above, where the diode to be used in the reverse conduction state is formed in addition to the lateral IGBT on the dielectric isolation substrate as described above, an additional area is needed for forming the trench isolation region and buffer regions, other than the area in which each of the high voltage devices is formed, thus causing a problem of an increased chip area.

### SUMMARY OF THE INVENTION

It is therefore an object of the present invention to provide a semiconductor apparatus equipped with lateral IGBT and lateral diode or lateral MOSFET, wherein the chip area is reduced as much as possible.

To accomplish the above object, there is provided according to the first aspect of the present invention a semiconductor apparatus which comprises a first semiconductor substrate that is of one of first and second conductivity types, a first oxide film formed on the first semiconductor substrate, a first conductivity type second semiconductor substrate that is formed on the first oxide film over the first semiconductor substrate, so as to provide a laminated substrate, and a trench that is formed through the second semiconductor substrate down to the first oxide film, a surface of the second semiconductor substrate that defines the trench being covered with a second oxide film, the trench being filled with a polycrystalline semiconductor so as to provide a dielectric isolation region, the second semiconductor substrate being divided by the trench into a plurality of isolated regions, wherein at least a lateral insulated gate bipolar transistor and a lateral diode are formed in the same one of the isolated regions.

In one preferred form of the first aspect of the invention, an emitter terminal of the lateral insulated gate bipolar transistor is connected to an anode terminal of the lateral diode, and a collector terminal of the lateral insulated gate bipolar transistor is connected to a cathode terminal of the lateral diode.

In another preferred form of the first aspect of the invention, a contact region of the lateral insulated gate bipolar transistor and an anode region of the lateral diode are formed as the same or common region. In a further preferred form of the invention, a cathode region of the lateral diode is formed in a surface layer of a buffer region of the lateral insulated gate bipolar transistor.

According to the second aspect of the present invention, a semiconductor apparatus similar to that as described above is provided in which a lateral MOSFET is formed in place of the lateral diode in the same isolated region in which the lateral insulated gate bipolar transistor is formed. In one preferred form of the second aspect of the invention, an emitter terminal of the lateral insulated gate bipolar transistor is connected to a source terminal of the lateral MOSFET, and a collector terminal of the lateral insulated gate bipolar transistor is connected to a drain terminal of the lateral MOSFET. In other preferred forms of this aspect of the invention, an emitter region of the lateral insulated gate bipolar transistor and a source region of the lateral MOSFET are formed as the same or common region, and/or a drain region of the lateral MOSFET is formed in a surface layer of a buffer region of the lateral insulated gate bipolar transistor.

In the semiconductor apparatus according to the first aspect of the invention, the lateral diode is incorporated in the apparatus to deal with reverse conduction of the lateral insulated gate bipolar transistor (hereinafter abbreviated to “lateral IGBT”), such that the anode terminal and cathode terminal of the lateral diode are respectively connected to the emitter terminal and collector terminal of the lateral IGBT. In this arrangement, the same voltage as that is applied to between the anode and cathode of the lateral diode is applied to between the emitter and collector of the lateral IGBT. Thus, there is no need to provide a trench isolation region for isolating the lateral diode from the lateral IGBT, and these lateral diode and IGBT may be formed in the same isolated region.

Where the lateral MOSFET is formed in place of the lateral diode, a parasitic diode formed by the lateral MOSFET may function in the same manner as the lateral diode described above. In this case, since the lateral MOSFET is connected in parallel with the lateral IGBT, forward current may flow through both of the lateral MOSFET and lateral IGBT, which leads to an increased amount of forward-conduction current.

In the semiconductor apparatus as described above, the two devices (lateral IGBT and lateral diode or lateral IGBT and lateral MOSFET) are fabricated in the same isolated region defined by the trench, and thus one of two isolated regions that have been conventionally needed for these two devices may be eliminated. Namely, one trench isolation region and adjacent buffer regions that surrounds the isolation region can be eliminated. In addition, the buffer region or contact region of the lateral IGBT and the cathode region or anode region of the lateral diode that adjoins the buffer or contact region, respectively, may be formed as the same or common region, so that the area of the isolated region having two devices can be further reduced. Similarly, the emitter region or buffer region of the lateral IGBT and the source region or drain region of the lateral MOSFET that adjoins the emitter or buffer region, respectively, may be formed as the same or common region, so that the area of the isolated region can be further reduced.

### BRIEF DESCRIPTION OF THE DRAWINGS

The invention will be described in greater detail with reference to a preferred embodiment thereof and the accompanying drawings, wherein:

FIG. 1 is a cross sectional view of a principal part of a semiconductor apparatus as the first embodiment of the present invention in which lateral IGBT and lateral diode are formed in the same isolated region;

FIG. 2 is a plan view, along with a cross sectional view, showing adjoining regions of the lateral IGBT and lateral diode of the apparatus of FIG. 1;

FIG. 3 is a view showing current distribution at the time when the semiconductor apparatus shown in FIG. 1 is forward-biased;

FIG. 4 is a view showing current distribution in the reverse conduction state of the semiconductor apparatus of FIG. 1;

FIG. 5 is a cross sectional view of a principal part of a semiconductor apparatus as the second embodiment of the present invention in which a lateral MOSFET is formed in place of the lateral diode of FIG. 1;

FIG. 6 is a circuit diagram showing the circuit configuration of MOSFET of FIG. 5 in which a reverse conduction current flows through a parasitic diode of the MOSFET;

FIG. 7 is a plan view, along with a cross sectional view, showing adjoining regions of the lateral IGBT and lateral MOSFET of the semiconductor apparatus of FIG. 5;

FIG. 8 is a view showing current distribution at the time when the semiconductor apparatus shown in FIG. 5 is forward-biased;

FIG. 9 is a view showing current distribution in the reverse conduction state of the semiconductor apparatus shown in FIG. 5;

FIG. 10 is a circuit diagram showing an inverter circuit.

FIG. 11(a) is a circuit diagram showing parasitic diodes of MOSFET through which current flows when the semiconductor apparatus is in the reverse conduction state, and FIG. 11(b) is circuit diagram showing IGBT provided with individual diodes through which current flows when the semiconductor apparatus is in the reverse conduction state;

FIG. 12 is a cross sectional view of a principal part of a typical example of known semiconductor apparatus in which the lateral IGBT and lateral diode are formed in respective isolated regions on a dielectric isolation substrate; and

FIG. 13 is a plan view, along with a cross sectional view, showing adjoining regions of the lateral IGBT and lateral diode of FIG. 12; and

FIG. 14 is a cross sectional view showing a portion of the semiconductor apparatus of FIG. 12 in the vicinity of a trench isolation region.

### DETAILED DESCRIPTION OF THE PREFERRED EMBODIMENTS

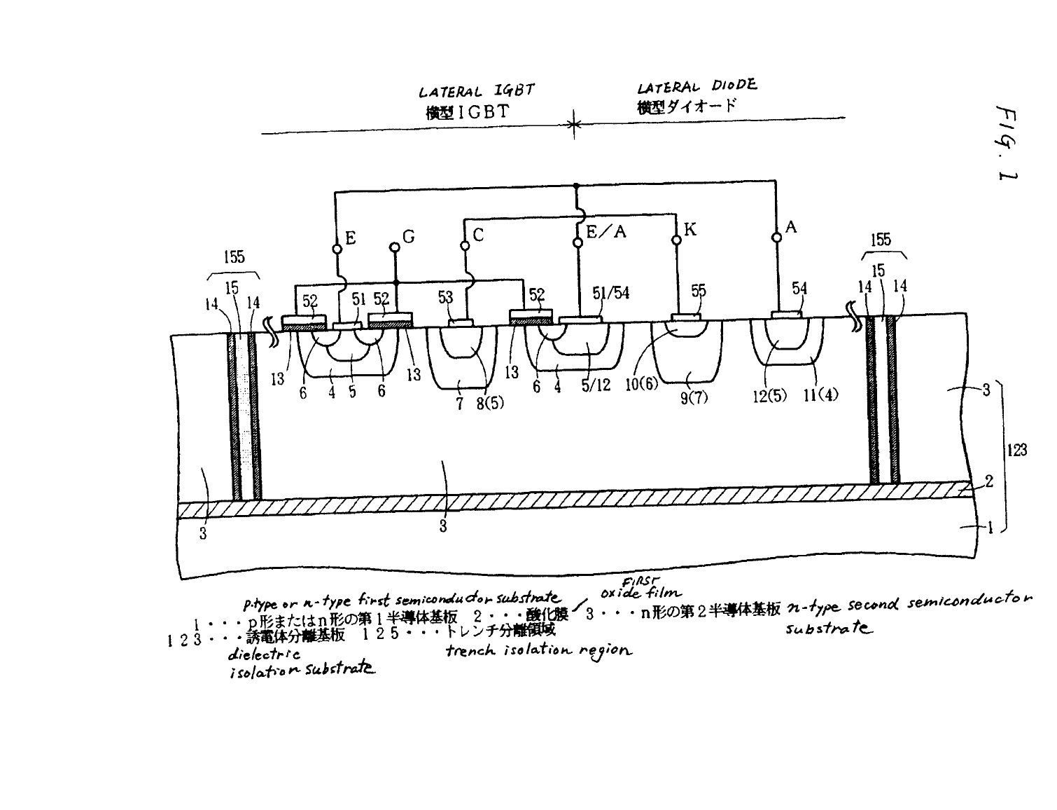

FIG. 1 is a cross sectional view of a principal part of the first embodiment of the present invention, wherein lateral IGBT and lateral diode are formed in the same isolated region. In this embodiment, the lateral IGBT is an n-channel type IGBT. It is to be understood that a p-channel IGBT may be provided by reversing the conductivity type of each region or element. As shown in FIG. 1, a first oxide film 2 is laminated on an n-type or p-type first semiconductor substrate 1, and an n-type second semiconductor substrate 3 (having a lower n-type impurity concentration than an n buffer region and a high resistance) is laminated on the first oxide film 2 over the first semiconductor substrate 1, so as to form an SOI substrate (laminated substrate). The second semiconductor substrate 3 is divided into a plurality of isolated regions by a trench that is formed through the second semiconductor substrate 3 down to the first oxide film 2. A surface of the second semiconductor substrate 3 that defines the trench is covered with a second oxide film 14, and the trench is filled with polycrystalline silicon 15, thereby to provide a tench isolation region 155. Thus, a dielectric isolation substrate 123 consisting of the first and second semiconductor substrates 1, 3 and first oxide film 2 is formed. The lateral IGBT and lateral diode are formed in a single isolated region (surrounded by the trench isolation region 155 and first oxide film 2) that is formed in the dielectric isolation substrate 123.

A method for forming a single lateral IGBT and lateral diode will be now described. A p well region 4 is formed in a surface layer of the isolated region of the n-type second semiconductor substrate 3, and an n buffer region 7 is formed apart from the p well region 4. An n⁺ emitter region 6 is formed in a surface layer of the p well region 4, and a p⁺ contact region 5 is formed in the p well region 4. A gate electrode 52 made of polycrystalline silicon is formed on a gate insulating film 13 over a portion of the p well region 4 that is interposed between the n-type semiconductor substrate 3 and the n⁺ emitter region 6. An emitter electrode 51 is formed on the n⁺ emitter region 6 and the p⁺ contact region 5. On the other hand, a p⁺ collector region 8 is formed in a surface layer of the n buffer region 7 at the same time that the p⁺ contact region 5 is formed (reference numeral 8 (5) means that these regions 8, 5 are concurrently formed), and a collector electrode 53 is formed on the p⁺ collector region 8. The emitter electrode 51 is connected to an emitter terminal E, and the collector electrode 53 is connected to a collector terminal C.

To form the lateral diode, an n diffusion region 9 and a p diffusion region 11 are formed in the surface layer of the same isolated region of the n-type semiconductor substrate 3, such that these diffusion regions 9, 11 are spaced apart from the p well region 4. An n⁺ cathode region 10 is formed in a surface layer of the n diffusion region 9, and a p⁺ anode region 12 is formed in a surface layer of the p diffusion region 11. Anode electrode 54 and cathode electrode 55 are formed on the p⁺ anode region 12 and n⁺ cathode region 10, respectively. The anode electrode 54 is connected to an anode terminal A, and the cathode electrode 44 is connected to a cathode terminal K. It is, however, to be noted that the p⁺ contact region 5 of the lateral IGBT and the p⁺ anode region 12 of the lateral diode are formed as a common region at a location where the n⁺ emitter region 6 of the lateral IGBT adjoins the lateral diode. Similarly, the emitter electrode 51 and the anode electrode 54 are formed as a common electrode, and the emitter terminal E and the anode terminal A provide a common terminal layer of the n buffer region 7 of the lateral IGBT in a region where the p⁺ collector region 8 of the lateral IGBT adjoins the n⁺ cathode region 10 of the lateral diode. Further, the emitter terminal E of the lateral IGBT is connected to the anode terminal A of the lateral diode, and the collector terminal C of the lateral IGBT is connected to the cathode terminal K of the lateral diode. In the case where the p⁺ collector region 8 of the lateral IGBT adjoins the n⁺ cathode region 10 at some location, the n⁺ cathode region 10 of the lateral diode is formed in a surface layer of the n buffer region 7 of the lateral IGBT in the adjoining areas, and the collector electrode 53 and cathode electrode 55 are formed as the same electrode, with the collector terminal C and cathode terminal E providing the same terminal. In this arrangement, the reverse current is allowed to flow through the lateral diode when the lateral IGBT is reverse-biased (when the IGBT is in the reverse conduction state).

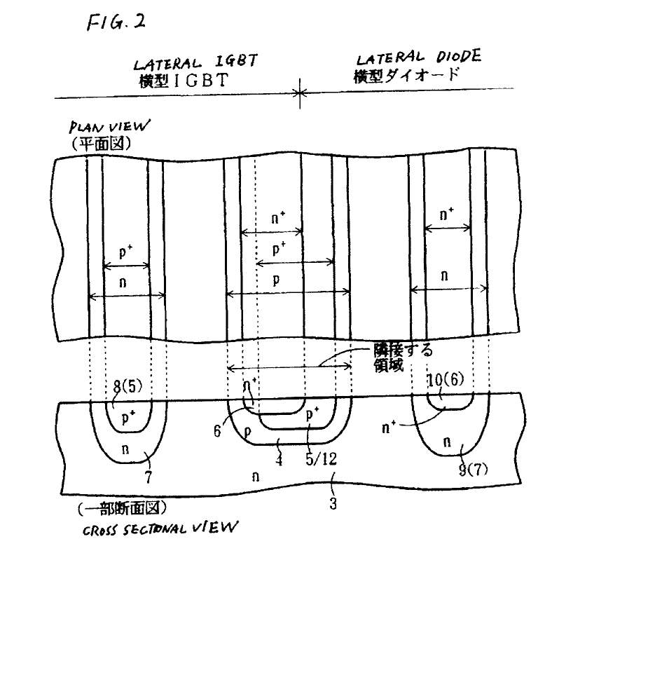

FIG. 2 contains a plan view and a cross sectional view of a portion of the first embodiment of FIG. 1 in which the lateral IGBT and the lateral diode are formed adjacent to each other. In FIG. 2, the IGBT is of n-channel type, and electrodes on the surface of the IGBT and diode are omitted. The plan view and cross sectional view of FIG. 2 are arranged such that the position of each element in one view is related to that of a corresponding element in the other view.

In the pattern shown in FIG. 2, the n⁺ emitter region 6 overlaps the p⁺ contact region 5 on the side of the IGBT in the region where the lateral IGBT adjoins the lateral diode, and this p⁺ contact region serves as the p⁺ anode region 12 on the side of the diode. Also, each of the regions in this pattern is formed in a stripe-like shape.

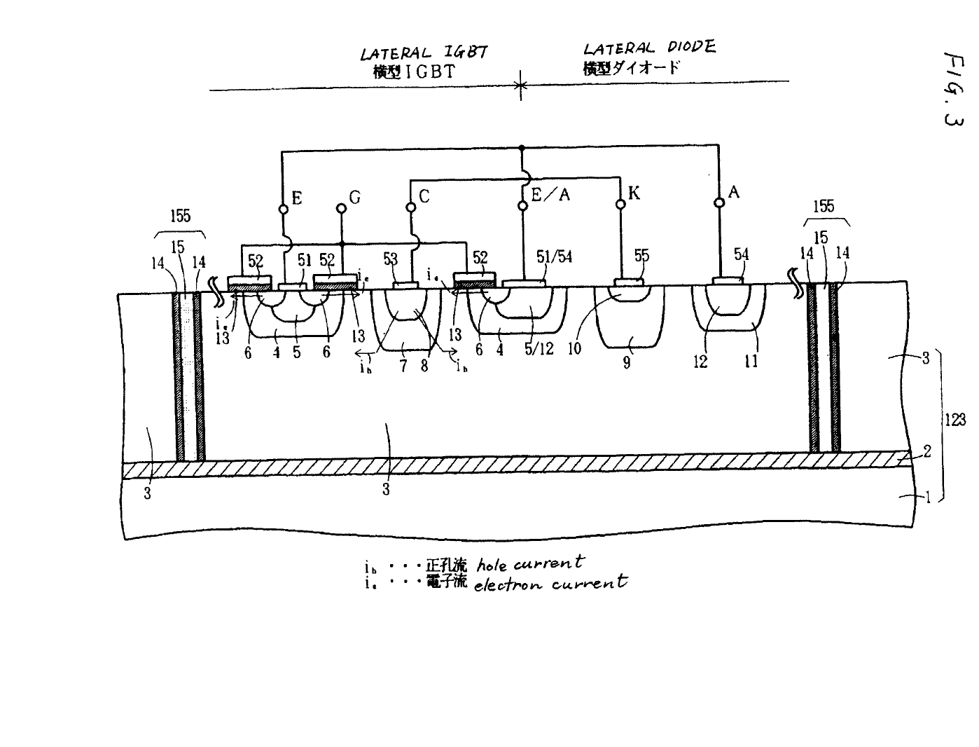

FIG. 3 shows current distribution at the time when the semiconductor apparatus shown in FIG. 1 is forward-biased. The current may be represented as electron current ie and hole current ih. In this operating mode, the current flows only through the lateral IGBT, and does not flow through the lateral diode since it is reverse-biased.

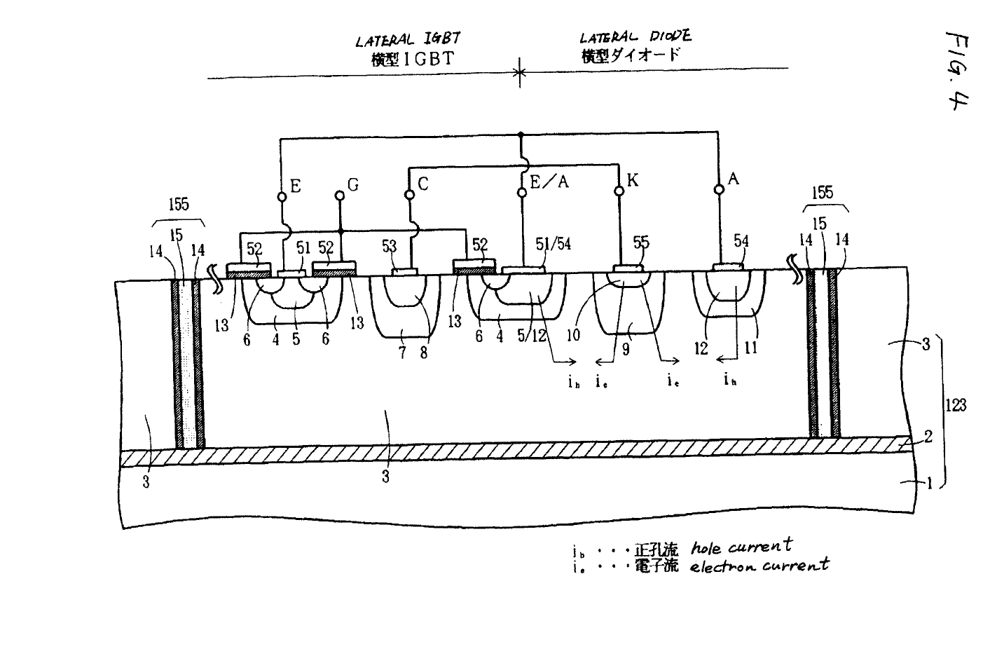

FIG. 4 shows current distribution at the time when the semiconductor apparatus shown in FIG. 1 is reverse-biased. In this case, the current flows through the lateral diode.

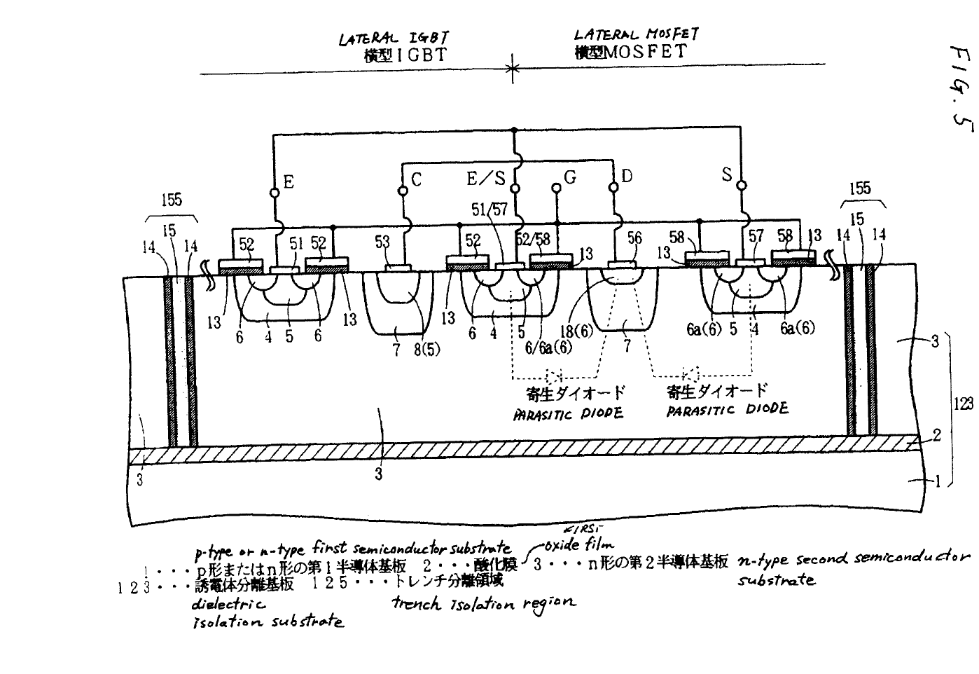

FIG. 5 is a cross sectional view of a principal part of the second embodiment of the present invention, wherein lateral MOSFET is formed in place of the lateral diode of FIG. 1. The lateral MOSFET is formed in substantially the same process as the lateral IGBT, except that an n⁺ drain region 18 is formed in the lateral MOSFET, in place of the p⁺ collector region of the lateral IGBT. The lateral IGBT uses a parasitic diode of the MOSFET as a diode through which current flows in the reverse conduction state of the IGBT. The parasitic diode as indicated by dotted lines in FIG. 5 is a pn diode that consists of p⁺ contact region 5, p well region 4, n buffer region 7 and n⁺ drain region 18. A gate electrode 58 of the lateral MOSFET is formed on a gate insulating film 13, and connected to a gate terminal G. A source electrode 57 is formed on n⁺ source region 6a and p⁺ contact region 5. In a region where the n⁺ emitter region 6 of the lateral IGBT adjoin the n⁺ source region 6a of the lateral MOSFET, the n⁺ emitter region 6 of the lateral IGBT and the n⁺ source region 6a of the lateral MOSFET are formed as a common region. In addition, the emitter electrode 51 and the source electrode 57 are formed as a common electrode, and the emitter terminal E and the source terminal S provide a common terminal. In the case where the p⁺ collector region 8 of the lateral IGBT adjoins the n⁺ drain region 18 of the lateral MOSFET at some location though not illustrated in FIG. 5, the n⁺ drain region 18 of the lateral MOSFET is formed in a surface layer of the n buffer region 7 of the lateral IGBT in the adjoining areas, and the collector electrode 53 and drain electrode 56 are formed as the same electrode, with the collector terminal C and drain terminal D providing the same terminal.

FIG. 6 is a circuit diagram showing the reverse conduction current that flows through the parasitic diode of the MOSFET of FIG. 1. This circuit is a part of a drive circuit for driving a plasma display, and a capacity load is connected to its output terminal D0. When the potential of the output terminal D0 becomes lower than the earth potential (zero potential), reverse conduction current ir flows through the parasitic diodes 20 as indicated by dotted lines.

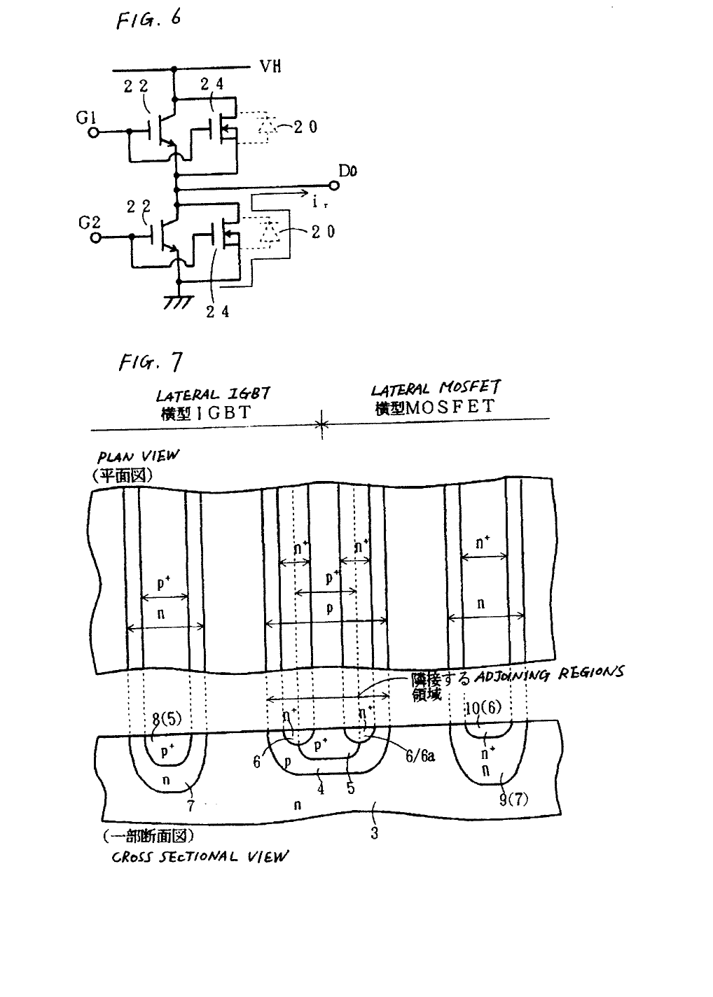

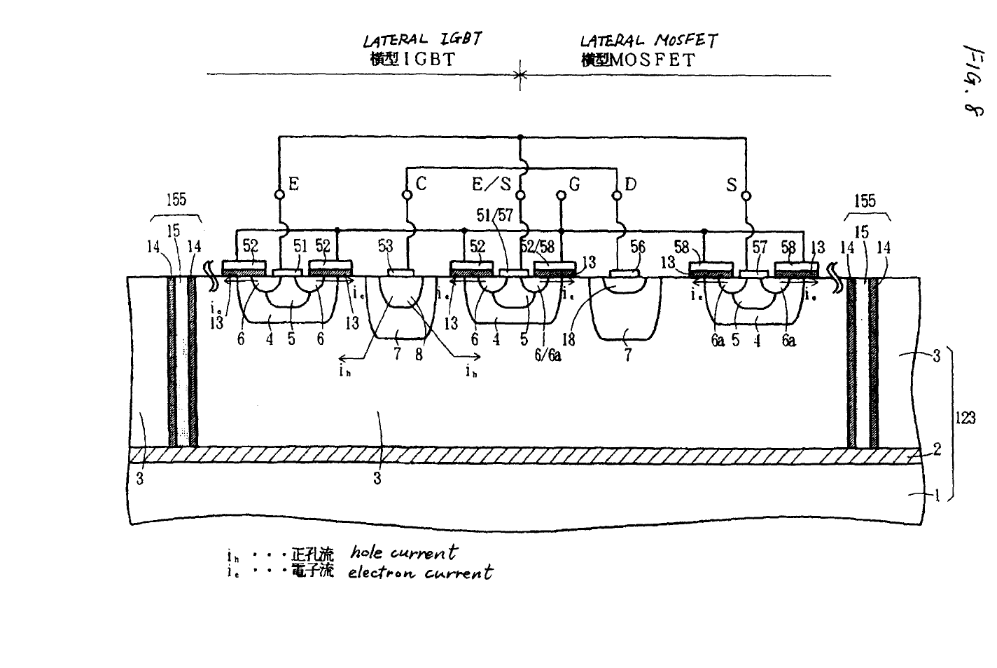

FIG. 7 contains a plan view and a cross sectional view showing adjoining regions of the lateral IGBT and lateral MOSFET of the second embodiment shown in FIG. 5. In this figure, the lateral IGBT and lateral MOSFET are of n-channel type, and the electrodes on the surface of the substrate are not shown. In FIG. 7, the n⁺ emitter region 6 of the lateral IGBT and the n⁺ source region 6a of the lateral MOSFET are formed as the same region at a location where the lateral IGBT adjoins the lateral MOSFET.

FIG. 8 shows current distribution at the time when the semiconductor apparatus shown in FIG. 5 is forward-biased. In this case, the lateral MOSFET as well as the lateral IGBT is forward-biased, and therefore the current flows through both of the lateral IGBT and lateral MOSFET. Accordingly, the semiconductor apparatus exhibits improved current driving capability when it is forward-biased, as compared with the embodiment of FIG. 1 in which the lateral diode is incorporated.

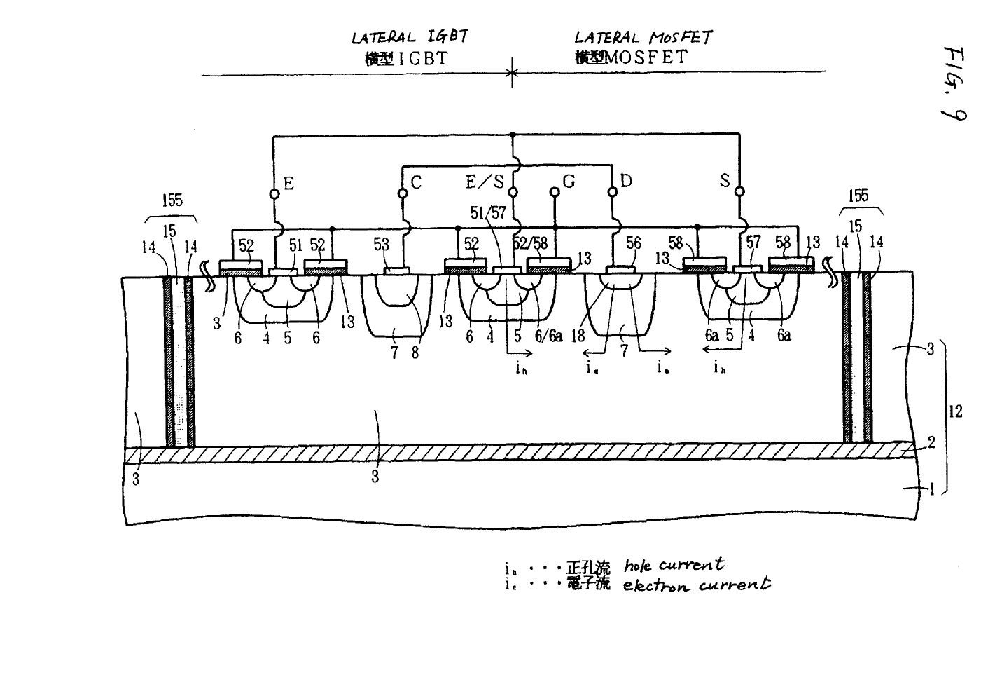

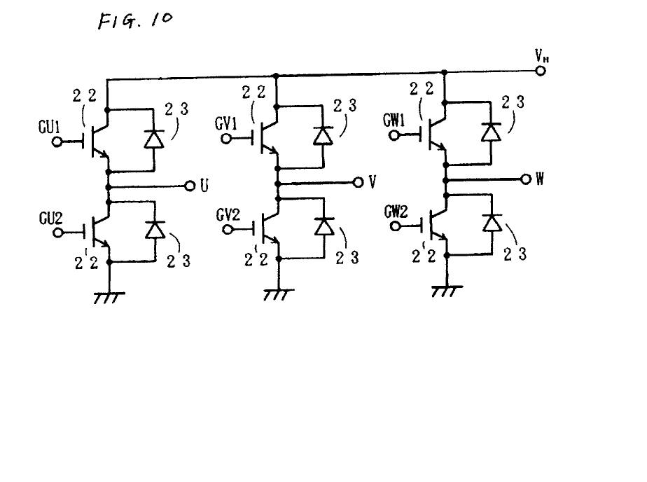

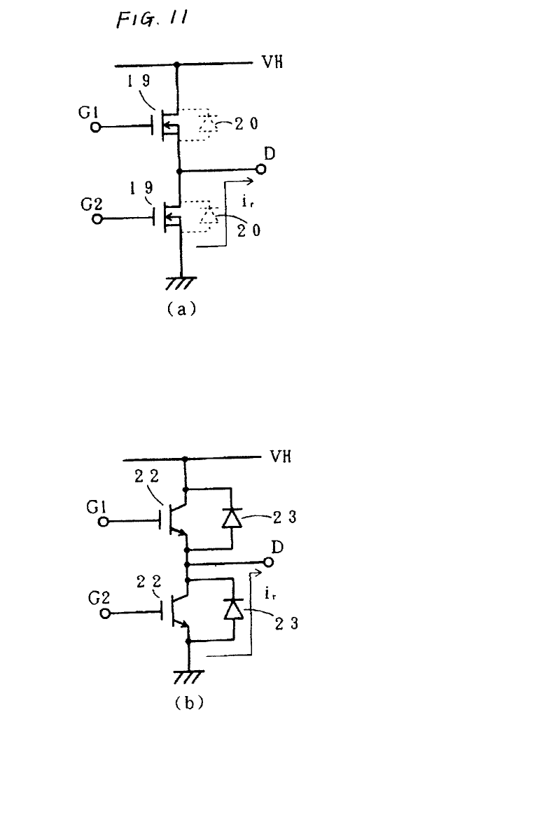

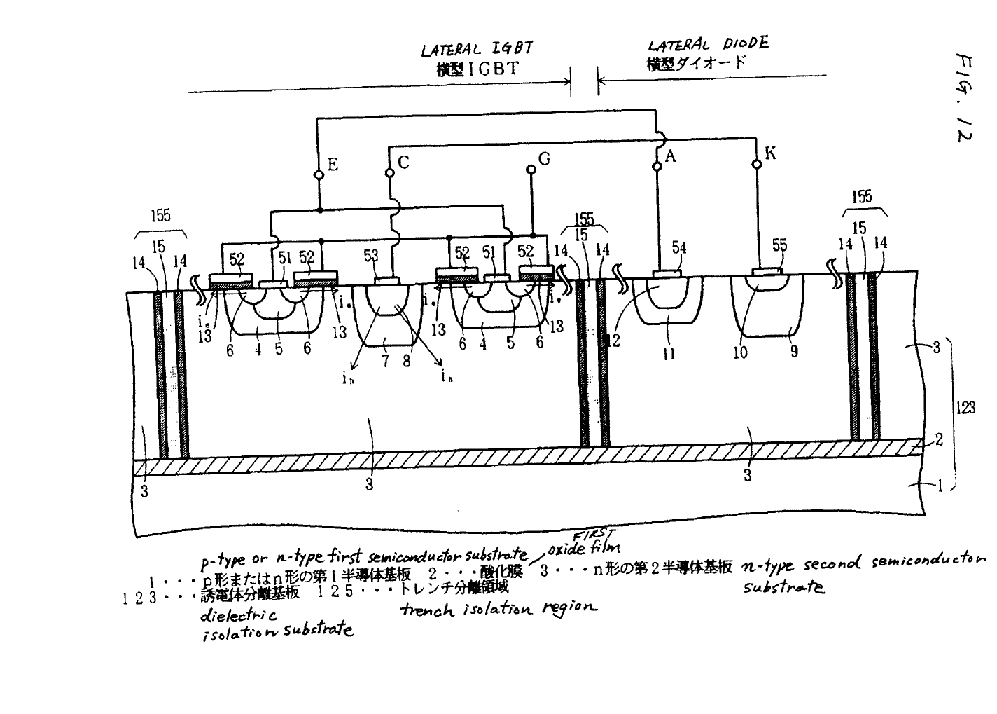

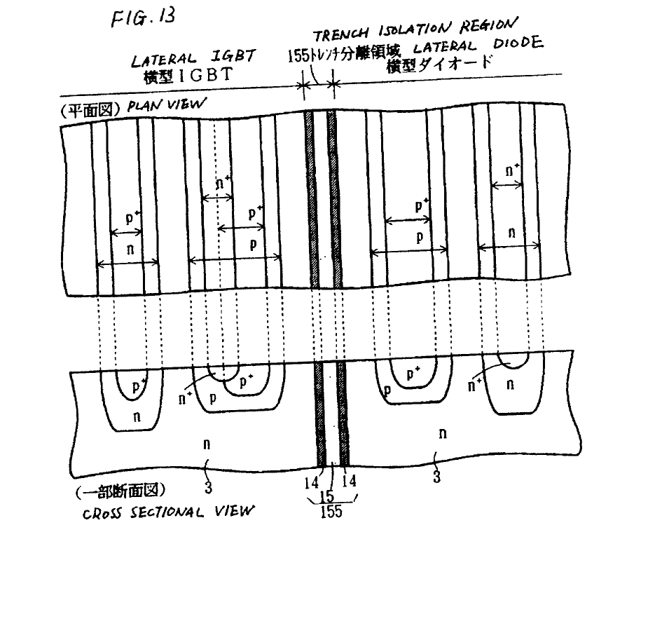

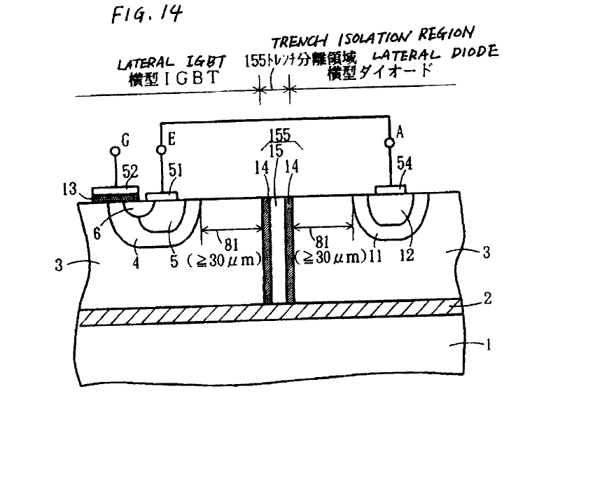

FIG. 9 shows current distribution at the time when the semiconductor apparatus of FIG. 6 is reverse-biased. In this case, the reverse conduction current flows through the parasitic diode of the lateral MOSFET, so as to produce electron current ie and hole current ih.

According to the present invention, the lateral diode incorporated for reverse conduction of the high voltage lateral IGBT formed on the dielectric isolation substrate may be formed in the same isolated region in which the lateral IGBT is formed, as in the first embodiment. This eliminates a need to provide a trench isolation region for isolating these two devices from each other and buffer regions that surrounds the isolation region, and thus the area required for forming the two devices can be reduced. In the region where the lateral IGBT and the lateral diode adjoin each other, the cathode region of the lateral diode may be formed in the buffer region of the lateral IGBT, or the p⁺ contact region of the lateral IGBT and the anode region of the lateral diode may be formed as a common region. Accordingly, the area of the isolated region in which the devices are formed can be reduced as compared with the case where the individual devices are formed in respective isolated regions. Consequently, the diode adapted for reverse conduction of the IGBT may be incorporated without significantly increasing an area of the resulting IC chip.

In the second embodiment in which the lateral IGBT and lateral MOSFET are formed in parallel with each other, a parasitic diode of the MOSFET may be utilized for allowing current to flow therethrough when the semiconductor apparatus is reverse-biased. In addition, when the semiconductor apparatus is forward-biased, the current may flow through the lateral MOSFET as well as the lateral IGBT. Thus, the current driving capability can be improved upon forward-bias conduction where the lateral MOSFET is incorporated, as compared with the case where the lateral diode is incorporated.

What is claimed is:

1. A semiconductor apparatus comprising:
a first semiconductor substrate that is of one of first and second conductivity types;
a first oxide film formed on said first semiconductor substrate;
a first conductivity type second semiconductor substrate that is formed on said first oxide film over said first semiconductor substrate, so as to provide a laminated substrate; and
a trench that is formed through said second semiconductor substrate down to said first oxide film, a surface of said second semiconductor substrate that defines said trench being covered with a second oxide film, said trench being filled with a polycrystalline semiconductor so as to provide a dielectric isolation substrate, said second semiconductor substrate being divided by said trench into a plurality of isolated regions;
wherein at least a lateral insulated gate bipolar transistor and a lateral diode are formed in the same one of said isolated regions.

2. A semiconductor apparatus according to claim 1, wherein said lateral insulated gate bipolar transistor has an emitter terminal and a collector terminal, and said lateral diode has an anode terminal and a cathode terminal, and wherein said emitter terminal is connected to said anode terminal, and said collector terminal is connected to said cathode terminal.

3. A semiconductor apparatus according to claim 1, wherein said lateral insulated gate bipolar transistor has an emitter region and a contact region, and said lateral diode has an anode region, and wherein said contact region and said anode region are formed as the same region in a region where said emitter region of the bipolar transistor adjoins said anode region of the lateral diode.

4. A semiconductor apparatus according to claim 1, wherein said lateral insulated gate bipolar transistor has a collector region and a buffer region, and said lateral diode has a cathode region, and wherein said cathode region is formed in a surface layer of said buffer region in a region where said collector region of the bipolar transistor adjoins said cathode region of the lateral diode.

5. A semiconductor apparatus, comprising:
a first semiconductor substrate that is of one of first and second conductivity types;
a first oxide film formed on said first semiconductor substrate;
a first conductivity type second semiconductor substrate that is formed on said first oxide film over said first semiconductor substrate, so as to provide a laminated substrate; and
a trench that is formed through said second semiconductor substrate down to said first oxide film, a surface of said second semiconductor substrate that defines said trench being covered with a second oxide film, said trench being filled with a polycrystalline semiconductor so as to provide a dielectric isolation region, said second semiconductor substrate being divided by said trench into a plurality of isolated regions;
wherein at least a lateral insulated gate bipolar transistor and a lateral MOSFET are formed in the same one of said isolated regions.

6. A semiconductor apparatus according to claim 5, wherein said lateral insulated gate bipolar transistor has an emitter terminal and a collector terminal, and said lateral MOSFET has a source terminal and a drain terminal, and wherein said emitter terminal is connected to said source terminal, and said collector terminal is connected to said drain terminal.

7. A semiconductor apparatus according to claim 5, wherein said lateral insulated gate bipolar transistor has an emitter region, and said lateral MOSFET has a source region, and wherein said emitter region and said source region are formed as a the same region in a region where said emitter region of the bipolar transistor adjoins said source region of the lateral MOSFET.

8. A semiconductor apparatus according to claim 5, wherein said lateral insulated gate bipolar transistor has a collector region and a buffer region, and said lateral MOSFET has a drain region, and wherein said drain region is formed in a surface layer of said buffer region in a region where the collector region of the bipolar transistor adjoins said drain region of the lateral MOSFET.
